(19) United States
(12) Patent Application Publication
(10) Pub. No.: US 2023/0387478 A1
(43) Pub. Date: Nov. 30, 2023

(54) METHOD OF PREDICTING DENDRITE GENERATION IN LITHIUM ION BATTERY

(71) Applicant: UIF (University Industry Foundation), Yonsei University, Seoul (KR)

(72) Inventors: Joon Sang LEE, Seoul (KR); Se Young KIM, Seoul (KR); Hae Gon LEE, Gyeongsangnam-do (KR)

(21) Appl. No.: 18/323,142

(22) Filed: May 24, 2023

(30) Foreign Application Priority Data
May 25, 2022 (KR) 10-2022-0063908

(51) Int. Cl. H01M 10/42; H01M 10/0567; H01M 10/48

(52) U.S. Cl. CPC H01M 10/4235; H01M 10/0567; H01M 10/4285; H01M 10/48; H01M 10/0525

(57) ABSTRACT

Disclosed therein are a dendrite growth prediction method and a computer program for predicting dendrite growth, which have an advantage of being able to simulate dendrite growth in real time like an actual battery using a lithium secondary battery simulator, thereby predicting dendrite growth at a molecular level according to a charging and discharging cycle and being able to shorten a prediction time by changing a calculation method for each electrode section, thereby rapidly predicting dendrite growth in real time. In addition, there is an advantage in which a specific additive is additionally added to the electrolyte, and thus whether dendrite growth is suppressed can be confirmed so that the dendrite suppression effect of a specific additive can be easily checked without an experiment using an actual lithium secondary battery.

### CROSS-REFERENCE TO RELATED APPLICATION

This application claims priority to and the benefit of Korean Patent Application No. 2022-0063908, filed on May 25, 2022, the disclosure of which is incorporated herein by reference in its entirety.

### BACKGROUND

### 1. Field of the Invention

The present invention relates to a method of predicting dendrite growth in a lithium-ion battery and a method of confirming the suppression of dendrite growth depending on the application of an additive.

### 2. Discussion of Related Art

Recently, electronic products, electronic devices, communication devices, and the like are being rapidly reduced in size and weight, and as the need for electric vehicles has emerged in relation to environmental issues, the demand for improving the performance of secondary batteries used as power sources for these products is also increasing. Among the power sources, lithium secondary batteries are attracting attention as high-performance batteries due to their high energy density and high standard electrode potential.

Among electrode active materials of the lithium secondary battery, lithium metal has an advantage of obtaining the highest energy density. However, a lithium metal electrode has problems such as formation of lithium dendrites during charging and discharging and corrosion of lithium due to a reaction between a surface of the lithium and an electrolyte, and thus the lithium metal electrode has not yet been commercialized.

However, in the case of lithium dendrites, the existing experimental analysis technology has a problem of only deriving images after charging and discharging, so it is necessary to develop a technology for simulating changes in dendrites in real time.

### RELATED ART DOCUMENT

### Patent Document

Japanese Patent Laid-open Application No. 2014-177113

### SUMMARY OF THE INVENTION

The objective of solving the above problems is as follows.

The present invention is directed to a dendrite growth prediction method, which can simulate the growth of dendrites in real time like a real battery using a lithium secondary battery simulator, and a method of confirming the suppression of dendrite growth due to the application of an additive.

According to an aspect of the present invention, there is provided a dendrite growth prediction method, which includes calculating an electronegativity of electrode atoms and electrolyte atoms, calculating partial charges of the electrode atoms and the electrolyte atoms from the electronegativity, deriving an interaction between the electrode atoms and the electrolyte atoms on the basis of the partial charges, determining whether a chemical reaction occurs between the electrode atoms and the electrolyte atoms on the basis of the interaction, deriving a variation in partial charge of the electrode atoms on the basis of whether the chemical reaction occurs, and predicting dendrite growth of the electrode atoms on the basis of the variation in partial charge.

According to another aspect of the present invention, there is provided a computer program stored in a computer readable medium, which includes commands for predicting dendrite growth using one or more processors, wherein the commands include calculating an electronegativity of electrode atoms and electrolyte atoms, calculating partial charges of the electrode atoms and the electrolyte atoms from the electronegativity, deriving an interaction between the electrode atoms and the electrolyte atoms on the basis of the partial charges, determining whether a chemical reaction occurs between the electrode atoms and the electrolyte atoms on the basis of the interaction, deriving a variation in partial charge of the electrode atoms on the basis of whether the chemical reaction occurs, and predicting dendrite growth of the electrode atoms on the basis of the variation in partial charge.

The predicting of the dendrite growth of the electrode atoms on the basis of the variation in partial charge may include predicting dendrite growth when a value of the partial charge of the electrode atoms is less than or equal to a preset value.

The determining of whether the chemical reaction occurs between the electrode atoms and the electrolyte atoms on the basis of the interaction may include determining that the electrode atoms and the electrolyte atoms are bonded and have undergone a chemical reaction when a value of a distance (r) between the electrode atom and the electrolyte atom, which is derived from the interaction, is less than or equal to a preset value.

The deriving of the interaction between the electrode atoms and the electrolyte atoms on the basis of the partial charges may include deriving an interaction on the basis of an interaction energy (E_{system}) between the electrode atoms and the electrolyte atoms, which is derived from the partial charges.

The calculating of the partial charges of the electrode atoms and the electrolyte atoms from the electronegativity may include calculating the partial charges through a variation in electronegativity with respect to a voltage applied to the electrode atoms and the electrolyte atoms.

The electrode atom may be an anode electrode atom.

The dendrite growth prediction method may further include confirming whether dendrite growth is suppressed by additionally adding a specific additive to the electrolyte.

The computer program stored in a computer readable medium may further include confirming whether dendrite growth is suppressed by additionally adding a specific additive to the electrolyte.

### BRIEF DESCRIPTION OF THE DRAWINGS

The above and other objects, features and advantages of the present invention will become more apparent to those skilled in the art by describing exemplary embodiments thereof in detail with reference to the accompanying drawings, in which:

FIG. 1 is a schematic flowchart illustrating a dendrite growth prediction method according to the present invention;

FIG. 2 is a diagram illustrating a voltage propagation process when an external voltage is applied to an electrode atoms and an electrolyte atoms according to an embodiment;

FIG. 3 is a diagram illustrating a variation in electronegativity after the external voltage is applied according to an embodiment;

FIG. 4 is a diagram illustrating a partial charge distribution reflecting varied electronegativity values according to an embodiment;

FIG. 5 is a schematic diagram illustrating a dendrite growth prediction method for all electrodes according to an embodiment;

FIG. 6 is a graph showing a comparison of a calculation time calculated by the dendrite growth prediction method for all electrodes and a calculation time calculated by a dendrite growth prediction method using a reactive force field ReaxFF with respect to a portion of a pseudo-cathode and an electrolyte according to an embodiment;

FIGS. 7A and 7B are graphs showing variations in volume of a lithium metal, which is an anode electrode, when an additive HF is not added (FIG. 7A) and when the additive HF is added (FIG. 7B) during periodic charging and discharging of a lithium secondary battery simulator according to one embodiment; and

FIGS. 8A and 8B are graphs showing variations in volume ratio due to the growth of a dendrite (Li cluster) predicted according to the dendrite growth prediction method when an additive HF is not added (FIG. 8A) and when the additive HF is added (FIG. 8B) during periodic charging and discharging of the lithium secondary battery simulator according to one embodiment.

### DETAILED DESCRIPTION OF EXEMPLARY EMBODIMENTS

Hereinafter, embodiments disclosed in the present specification will be described in detail with reference to the drawings. The same reference numerals are given to the same or similar components regardless of reference numerals, and a repetitive description thereof will be omitted. As used herein, suffixes “module” and “portion” for a component of the present invention are given or interchangeably used solely for ease of preparation of the specification, and each does not have a distinct meaning or role in itself. Further, in the following description of the present specification, when a detailed description of known related art is determined to obscure the gist of the present specification, the detailed description thereof will be omitted herein. In addition, the accompanying drawings are merely for easy understanding of the embodiments disclosed in the present specification, the technical spirit disclosed in the present specification is not limited by the accompanying drawings, and it should be understood that all modifications, equivalents, and substitutes are included in the spirit and scope of the present disclosure.

Terms including ordinal numbers such as first, second, and the like used herein may be used to describe various components, but the various components are not limited by these terms. The terms are used only for the purpose of distinguishing one component from another component.

When a component is referred to as being “connected” or “coupled” to another component, the component may be directly connected or coupled to another component, but it should be understood that sill another component may be present between the component and another component. Contrarily, when a component is referred to as being “directly connected,” or “directly coupled” to other component, it should be understood that another component may not be present between the component and the other component.

Each component shown in the present specification is independently illustrated to indicate different characteristic functions and does not mean that each component is composed of separate hardware or a single software component unit. That is, each component is enumerated and included as each component for convenience of description, and at least two components can be combined to form one component, or one component can be divided into a plurality of components to perform a function, and each of these components can be divided into a plurality of components. Integrated embodiments and separated embodiments of the components also fall in the scope of the present invention unless departing from the gist of the present invention.

In addition, some of the components may be optional components for improving performance rather than essential components that perform essential functions in the present invention. The present invention can be implemented by including only components essential to implement the gist of the present invention, excluding components used for performance improvement, and a structure including only essential components excluding optional components used for performance improvement also falls in the scope of the present invention.

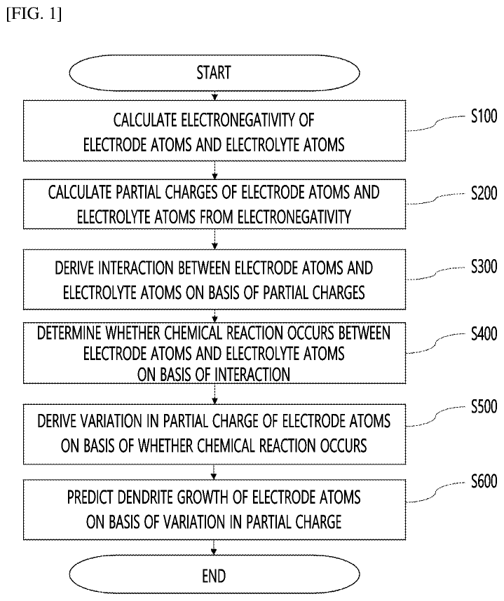

FIG. 1 is a schematic flowchart illustrating a dendrite growth prediction method according to the present invention. Referring to FIG. 1, the dendrite growth prediction method includes calculating the electronegativity of electrode atoms and electrolyte atoms (S100), calculating partial charges of the electrode atoms and the electrolyte atoms from the electronegativity (S200), deriving an interaction between the electrode atoms and the electrolyte atoms on the basis of the partial charges (S300), determining whether a chemical reaction occurs between the electrode atoms and the electrolyte atoms on the basis of the interaction (S400), deriving a variation in partial charge of the electrode atoms on the basis of whether the chemical reaction occurs (S500), and predicting dendrite growth of the electrode atoms on the basis of the variation in partial charge (S600).

According to the present invention, the calculating of the electronegativity of the electrode atoms and the electrolyte atoms (S100) includes calculating a final electronegativity by measuring the varied electronegativity after an external voltage is applied to the electrode atoms and the electrolyte atoms included in a lithium secondary battery simulator.

According to the embodiment, the final electronegativity of the electrode atoms and the electrolyte atoms may be calculated using an electrochemical dynamics with implicit degrees of freedom (EChemDID) method.

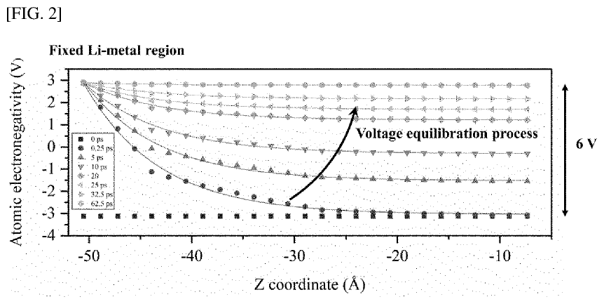

FIG. 2 is a diagram illustrating a voltage propagation process when an external voltage is applied to an electrode atom and an electrolyte atom according to an embodiment.

Referring to FIG. 2, as the time after the application of the external voltage increases from 0 ps to 62.5 ps, it can be confirmed that the voltage is successfully propagated to the lithium secondary battery simulator.

The electronegativity due to the external voltage applied to the electrode atoms may be calculated from the following Equation 1.

Xᵢ*=Xᵢ⁰±Φᵢ/2 [Equation 1]

Xᵢ* denotes the final electronegativity, Xᵢ⁰ denotes electronegativity before the application of the external voltage, and Φᵢ denotes an electrochemical potential to which the external voltage is applied.

In this case, a variation in electronegativity according to the voltage propagation may be calculated as in the following Equation 2.

$${\dot{Φ}}_{i} ( t ) = k {\sum }_{j \neq i} \frac{{Φ}_{i} ( t ) - {Φ}_{j} ( t )}{{\vert {R}_{i j} \vert}^{2}} ω ( {R}_{i j} ) - η F ( {W}_{i} ) {Φ}_{i} \qquad [ Equation 2 ]$$

Φᵢ(t) denotes an electronegativity variation value, k denotes effective diffusivity, η denotes a relaxation rate, Rᵢⱼ denotes a distance between atom i and atom j, w(Rᵢⱼ) denotes a local weighting function, F(Wᵢ) denotes a switching function, and Wi denotes total metallic coordinates.

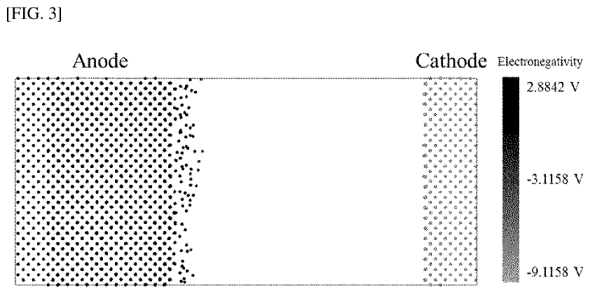

FIG. 3 is a diagram illustrating a variation in electronegativity after the external voltage is applied according to an embodiment.

Referring to FIG. 3, it can be confirmed that the electronegativity variation value calculated according to Equation 2 is reflected.

Finally, the final electronegativity value may be calculated by applying the electronegativity variation value, which is calculated according to Equation 2, to the following Equation 3.

Xᵢ*(t)=Xᵢ⁰+Φᵢ(t) [Equation 3]

Xᵢ* denotes the final electronegativity, Xᵢ⁰ denotes the electronegativity before the application of the external voltage, and Φᵢ denotes the electronegativity variation value.

According to the present invention, the calculating of the partial charges of the electrode atoms and the electrolyte atoms from the electronegativity (S200) is an operation of calculating the partial charges of the electrode atoms and the electrolyte atoms through the variation in electronegativity with respect to the applied voltage.

According to one embodiment, the partial charges of the electrode atoms and the electrolyte atoms may be calculated using a charge equilibration (ACKS2) method.

Specifically, partial charge values of the electrode atoms and the electrolyte atoms may be calculated by applying the final electronegativity value, which is derived through operation S100, to the following Equation 4.

$$e = {\sum }_{i} {q}_{i} {χ}_{i} + \frac{1}{2} {\sum }_{i} {q}_{i} {q}_{j} {J}_{ij} \qquad [ Equation 4 ]$$

e denotes molecular electrical circuits, X* denotes the final electronegativity, qᵢ denotes a partial charge of atom i, qⱼ denotes a partial charge of atom j, and Jᵢⱼ denotes a screened Coulomb interaction between atom i and atom j.

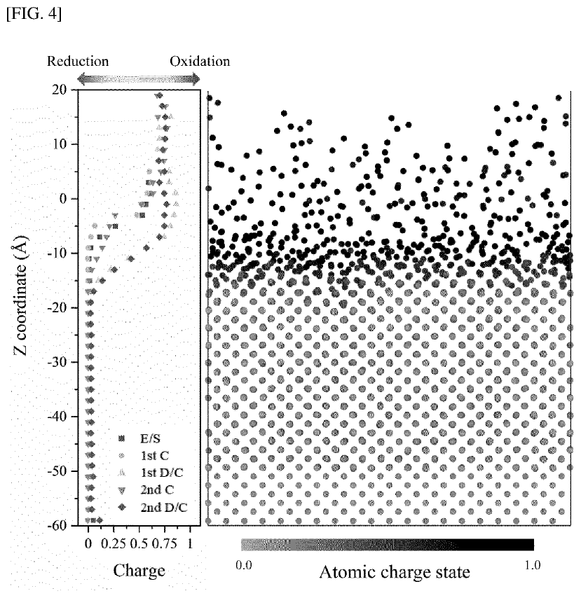

FIG. 4 is a diagram illustrating a partial charge distribution reflecting varied electronegativity values according to an embodiment.

Referring to FIG. 4, it can be seen that partial charge distribution values of the electrode atoms and the electrolyte atoms, which are derived through Equation 4, are reflected.

According to the present invention, the deriving of the interaction between the electrode atoms and the electrolyte atoms on the basis of the partial charges (S300) is an operation of deriving the interaction energy E_{system} between the electrode atoms and the electrolyte atoms.

According to one embodiment, the interaction energy E_{system} between the electrode atoms and the electrolyte atoms, which includes the Coulomb energy E_{coulomb} between the electrode atoms and the electrolyte atoms, may be derived by utilizing a reactive force field ReaxFF.

E_{system}=E_{vdW}+E_{coulomb}+E_{intramolecular} [Equation 5]

E_{system} denotes the interaction energy between the electrode atoms and the electrolyte atoms, E_{vdW} denotes the Van der Waals energy between the electrode atoms and the electrolyte atoms, E_{coulomb} denotes the Coulomb energy between the electrode atoms and the electrolyte atoms, and E_{intramolecular} denotes the energy between atoms in a molecule.

In this case, the Coulomb energy E_{coulomb} between the electrode atoms and the electrolyte atoms may be derived by applying the partial charge values of the electrode atoms and the electrolyte atoms, which are derived in operation S200, to the following Equation 6.

$${E}_{coulomb} = C \cdot \frac{{q}_{i} \cdot {q}_{j}}{{[ {r}_{i j}^{3} + {( \frac{1}{{γ}_{i j}} )}^{3} ]}^{\frac{1}{3}}} \qquad [ Equation 6 ]$$

C denotes Coulomb's constant, qᵢ and qⱼ denote atomic charges, rᵢⱼ denotes interatomic distances, and yᵢⱼ denotes a shielding parameter.

Meanwhile, the Van der Waals energy E_{vdW} between the electrode atoms and the electrolyte atoms may be derived through the following Equation 7, and the interatomic energy in the molecule Entramolecular may be derived through the following Equation 8.

$${E}_{vdW} = {D}_{ij} \cdot \{ exp [ {α}_{ij} \cdot ( 1 - \frac{{f}_{13} ( {r}_{ij} )}{{r}_{vdW}} ) ] - 2 \cdot exp [ \frac{1}{2} \cdot {α}_{ij} \cdot ( 1 - \frac{{f}_{13} ( {r}_{ij} )}{{r}_{vdW}} ) ] \} \qquad [ Equation 7 ]$$

Dᵢⱼ denotes an energy well depth (defined relative to the dissociated atoms), aᵢⱼ denotes a control parameter of a potential “width,” rᵢⱼ denotes a distance between the atoms, and r_{vdW} denotes an equilibrium bond distance.

$${f}_{13} ( {r}_{i j} ) = {[ {r}_{i j}^{{p}_{vdW 1}} + {( \frac{1}{{γ}_{w}} )}^{{p}_{vdW 1}} ]}^{1 / {p}_{vdW 1}}$$

y_{w}, p_{vdW1} denotes a shielding parameter.

E_{intramolecular}=E_{bond}+Eₒᵥₑᵣ+E_{angle} [Equation 8]

E_{bond}=−Dₑ·BOᵢⱼ·exp[p_{be,1}(1−BOᵢⱼ^{p}^{_{be,1}})]

Dₑ, p_{be,1} denote an empirical parameter, and BOᵢⱼ denotes a bond order.

$${E}_{over} = {p}_{over} \cdot {Δ}_{i} \cdot ( \frac{1}{1 + exp ( {λ}_{over} \cdot {Δ}_{i} )} )$$

pₒᵥₑᵣ and λₒᵥₑᵣ denote empirical parameters, and Δᵢ denotes a degree of deviation of the sum of the uncorrected bond orders around an atomic center.

E_{angle}=[1−exp(λ_{angle}·BOₐ³]

λ_{angle} and kₐ, k_{b} denote empirical parameters, BOₐ denotes a bond order a, BO_{b} denotes a bond order b, ϕ denotes an angle, and ϕ₀ denotes an equilibrium angle.

According to the present invention, the determining of whether the chemical reaction occurs between the electrode atoms and the electrolyte atoms on the basis of the interaction (S400) is an operation of determining that, when a value of a distance r between the electrode atom and the electrolyte atom, which is derived from the interaction (S300), is less than or equal to a preset value, the electrode atoms and the electrolyte atoms are bonded and have undergone a chemical reaction.

According to one embodiment, the value of the distance r between the electrode atom and the electrolyte atom may be derived from the interaction energy E_{system} between the electrode atoms and the electrolyte atoms calculated through operation S300 by applying the following Equation 9.

F=−∇E_{system}=m\vec{a}

\vec{v}(t+Δt)=\vec{v}(t)+½\vec{a}(t)Δt

\vec{x}(t+Δt)=\vec{x}(t)+\vec{v}(t)Δt½\vec{a}Δt²

rᵢⱼ=|xᵢ−xⱼ| [Equation 9]

F denotes a force, m denotes a mass, a denotes acceleration, v denotes a velocity, x denotes a position, and rᵢⱼ denotes an atomic distance.

According to one embodiment, the bond order between the electrode atoms and the electrolyte atoms may be derived from the value of the distance r between the electrode atom and the electrolyte atom calculated through Equation 9 by applying the following Equation 10.

$${BO}_{ij}^{′} = {BO}_{i j}^{σ} + {BO}_{i j}^{π} + {BO}_{i j}^{π π} = exp [ {p}_{b o 1} \cdot {( \frac{{r}_{i j}}{{r}_{o}^{σ}} )}^{{p}_{b o 2}} ] + exp [ {p}_{b o 3} \cdot {( \frac{{r}_{i j}}{{r}_{o}^{π}} )}^{{p}_{b o 4}} ] + exp [ {p}_{b o 5} \cdot {( \frac{{r}_{i j}}{{r}_{o}^{π π}} )}^{{p}_{b o 6}} ] \qquad [ Equation 10 ]$$

rᵢⱼ denotes an interatomic distance, rₒ denotes an equilibrium bond length, and p_{bo} denotes an empirical parameter.

In this way, as a result of deriving a relationship between the value of the distance r and the bond order between the electrode atoms and the electrolyte atoms, when the bond order is a value of 1 or more, it can be regarded that the atoms are bonded, and when the bond order is a value of 0, it can be regarded that the atoms are not bonded.

Consequently, when the value of the distance r between the electrode atom and the electrolyte atom is less than or equal to a preset first value, it can be determined that the electrode atoms and the electrolyte atoms are bonded and have undergone a chemical reaction, whereas, when the value of the distance r between the electrode atom and the electrolyte atom exceeds the preset first value, it can be determined that the electrode atoms and the electrolyte atoms are not bonded and have not undergone a chemical reaction

In this case, the preset first value may be derived according to repetitive experimental results and may be 0.3 Å or less. However, the above value corresponds to an example for describing the present invention, and the preset first value is not limited to the above value.

According to the present invention, the deriving of the variation in partial charge of the electrode atoms on the basis of whether the chemical reaction occurs (S500) is an operation of deriving, when it is determined that the electrode atoms and the electrolyte atoms are bonded and have undergone a chemical reaction through operation S400, a varied partial charge of the electrode atoms due to the chemical reaction.

In this case, a method of deriving the varied partial charge of the electrode atoms may use the above-described Equation 4.

According to the present invention, the predicting of the dendrite growth of the electrode atoms on the basis of the variation in partial charge (S600) is an operation predicting dendrite growth when a value of the partial charge of the electrode atoms derived in operation S500 is less than or equal to a preset value.

Specifically, when the derived value of the partial charge of the electrode atoms is less than or equal to a preset second value, it can be predicted that a dendrite is generated due to complete reduction, whereas, when the derived value of the partial charge of the electrode atoms exceeds the preset second value, it can be predicted that it is in an oxidation-reduction state in a normal charging and discharging state.

In this case, the preset second value may be derived according to repetitive experimental results and may be 0.1 or less. Similarly, the above value corresponds to an example for describing the present invention, and the preset second value is not limited to the above value.

According to the present invention, the electrode atoms used in the dendrite growth prediction method may be anode electrode atoms. According to one embodiment, the anode electrode atom may be a lithium atom.

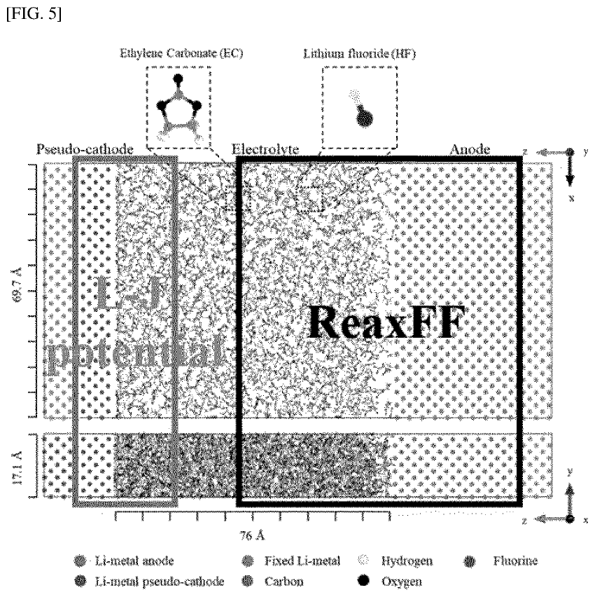

FIG. 5 is a schematic diagram illustrating a dendrite growth prediction method for all electrodes according to an embodiment.

Referring to FIG. 5, it can be confirmed that the dendrite growth was predicted in a portion of the anode and the electrolyte using the reactive force field ReaxFF to which the bond order calculation formula between the electrode atoms and the electrolyte atoms was applied in operation S300, and the dendrite growth was calculated in a portion of the pseudo-cathode and the electrolyte through an L-J potential (Equation 11) without applying the bond order calculation formula between the electrode atoms and the electrolyte atoms.

$${V}_{LJ} ( r ) = 4 ε [ {( \frac{σ}{r} )}^{12} - {( \frac{σ}{r} )}^{6} ] \qquad [ Equation 11 ]$$

r denotes a distance between two interacting particles, ε denotes dispersion energy, and σ denotes a size of the particle.

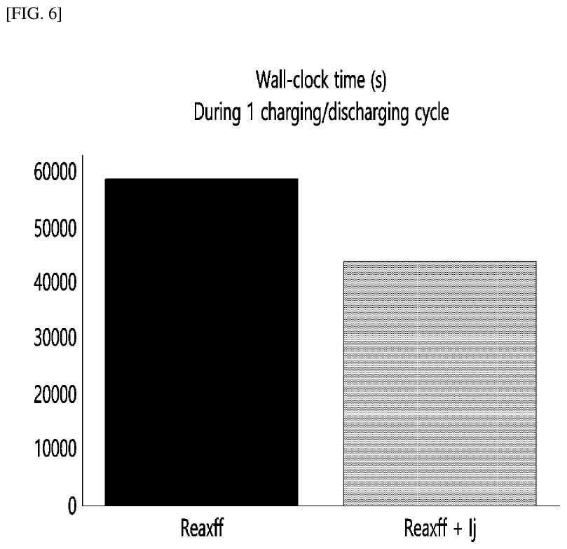

FIG. 6 is a graph showing a comparison of a calculation time calculated by the dendrite growth prediction method for all electrodes and a calculation time calculated by a dendrite growth prediction method using a reactive force field ReaxFF with respect to a portion of the pseudo-cathode and an electrolyte according to an embodiment.

Referring to FIG. 6, it can be confirmed that the calculation time calculated by the dendrite growth prediction method for all electrodes according to the embodiment was reduced by 25% compared to the calculation time calculated by a dendrite growth prediction method using a reactive force field ReaxFF with respect to a portion of the pseudo-cathode and the electrolyte.

That is, the dendrite growth prediction method according to the present invention has an advantage of quickly predicting dendrite growth for the anode electrode portion by effectively and accurately predicting dendrite growth in the anode electrode part, where there is a concern about dendrite formation, using the reactive force field ReaxFF to which the interaction energy between the electrode atoms and the electrolyte atoms is applied and in the cathode electrode portion, where there is no concern about dendrite formation, using the L-J potential excluding the bond order derivation process.

The dendrite growth prediction method according to the present invention may further include confirming whether the dendrite growth is suppressed by additionally adding a specific additive to the electrolyte.

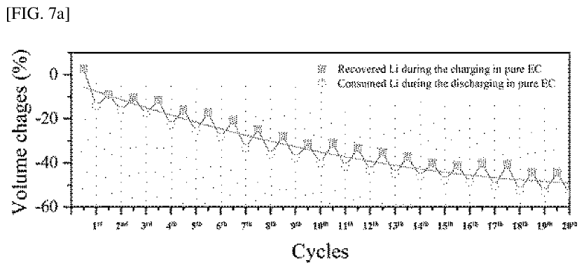

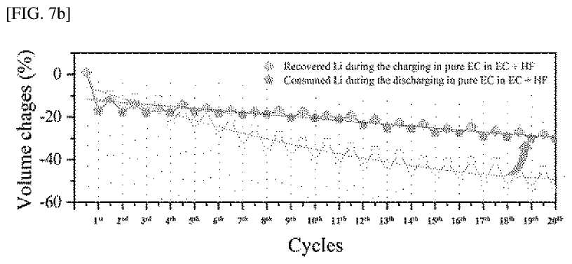

FIGS. 7A and 7B are graphs showing variations in volume of a lithium metal, which is an anode electrode, when an additive HF is not added (FIG. 7A) and when the additive HF is added (FIG. 7B) during periodic charging and discharging of a lithium secondary battery simulator according to one embodiment.

Referring to FIGS. 7A and 7B, it can be seen that, when the additive HF was not added, a volume of a lithium metal was generally reduced during periodic charging and discharging of the lithium secondary battery simulator, whereas, when the additive HF was added, the volume of the lithium metal was not relatively reduced.

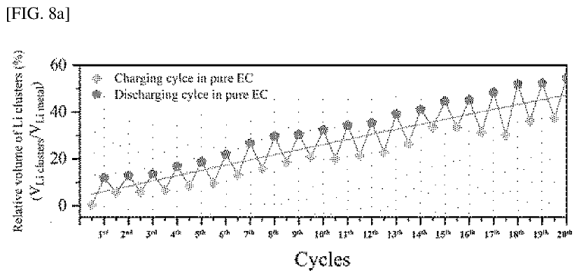

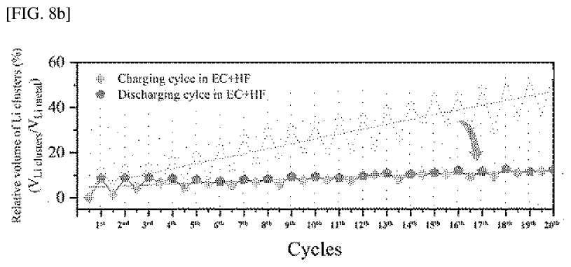

FIGS. 8A and 8B are graphs showing variations in volume ratio due to the growth of a dendrite (Li cluster) predicted according to the dendrite growth prediction method when an additive HF is not added (FIG. 8A) and when the additive HF is added (FIG. 8B) during periodic charging and discharging of the lithium secondary battery simulator according to one embodiment.

Referring to FIGS. 8A and 8B, it can be seen that, when the additive HF was not added, a growth rate of a dendrite (Li cluster) increased during periodic charging and discharging of the lithium secondary battery simulator, whereas, when the additive HF was added, the growth rate of a dendrite (Li cluster) did not increase relatively.

That is, the method of predicting dendrite growth using the lithium secondary battery simulator according to the present invention has an advantage of being able to easily determine whether dendrite growth is suppressed according to the application of a specific additive in real time, thereby easily checking the dendrite suppression effect of a specific additive without an experiment using an actual lithium secondary battery.

In addition, the present invention relates to a computer program stored in a computer-readable medium, the computer program includes commands for predicting dendrite growth through one or more processors, and the commands includes calculating the electronegativity of electrode atoms and electrolyte atoms, calculating partial charges of the electrode atoms and the electrolyte atoms from the electronegativity, deriving an interaction between the electrode atoms and the electrolyte atoms on the basis of the partial charges, determining whether a chemical reaction occurs between the electrode atoms and the electrolyte atoms on the basis of the interaction, deriving a variation in partial charge of the electrode atoms on the basis of whether the chemical reaction occurs, and predicting dendrite growth of the electrode atoms on the basis of the variation in partial charge.

In this case, among the description of the computer program, contents overlapping those described in the dendrite growth prediction method may be omitted.

Those skilled in the art to which the present invention pertains can understand that various illustrative logical blocks, modules, processors, parts, circuits, and algorithm operations described in connection with the embodiments disclosed herein can be implemented by electronic hardware, programs or design code in various forms (for convenience, referred to as software herein), or a combination thereof.

The above-described present invention can be implemented as computer-readable code in a medium on which a program is recorded. The computer-readable medium includes all types of recording devices in which data readable by a computer system is stored. Examples of the computer-readable medium include hard disk drives (HDDs), solid state disks (SSDs), silicon disk drives (SDDs), read only memories (ROMs), random access memories (RAMs), compact disc ROMs (CD-ROMs), magnetic tapes, floppy disks, and optical data storage devices.

In accordance with a dendrite growth prediction method according to the present invention, there is an advantage of being able to simulate dendrite growth in real time like an actual battery using a lithium secondary battery simulator, thereby predicting dendrite growth at a molecular level according to a charging and discharging cycle.

In addition, in accordance with a dendrite growth prediction method according to the present invention, there is an advantage of being able to shorten a prediction time by changing a calculation method for each electrode section, thereby rapidly predicting dendrite growth in real time.

In addition, in accordance with a dendrite growth prediction method according to the present invention, there is an advantage of being able to determine in real time whether dendrite growth is suppressed according to the application of a specific additive, thereby easily checking the dendrite suppression effect of a specific additive without an experiment using an actual lithium secondary battery.

What is claimed is:

1. A dendrite growth prediction method, comprising:
calculating an electronegativity of electrode atoms and electrolyte atoms;
calculating partial charges of the electrode atoms and the electrolyte atoms from the electronegativity;
deriving an interaction between the electrode atoms and the electrolyte atoms on the basis of the partial charges;
determining whether a chemical reaction occurs between the electrode atoms and the electrolyte atoms on the basis of the interaction;
deriving a variation in partial charge of the electrode atoms on the basis of whether the chemical reaction occurs; and
predicting dendrite growth of the electrode atoms on the basis of the variation in partial charge.

2. The method of claim 1, wherein the predicting of the dendrite growth of the electrode atoms on the basis of the variation in partial charge includes predicting dendrite growth when a value of the partial charge of the electrode atoms is less than or equal to a preset value.

3. The method of claim 1, wherein the determining of whether the chemical reaction occurs between the electrode atoms and the electrolyte atoms on the basis of the interaction includes determining that the electrode atoms and the electrolyte atoms are bonded and have undergone a chemical reaction when a value of a distance (r) between the electrode atom and the electrolyte atom, which is derived from the interaction, is less than or equal to a preset value.

4. The method of claim 1, wherein the deriving of the interaction between the electrode atoms and the electrolyte atoms on the basis of the partial charges includes deriving an interaction on the basis of an interaction energy (E_{system}) between the electrode atoms and the electrolyte atoms, which is derived from the partial charges.

5. The method of claim 1, wherein the calculating of the partial charges of the electrode atoms and the electrolyte atoms from the electronegativity includes calculating the partial charges through a variation in electronegativity with respect to a voltage applied to the electrode atoms and the electrolyte atoms. atom.

6. The method of claim 1, wherein the electrode atom is an anode electrode

7. The method of claim 1, further comprising confirming that dendrite growth is suppressed by additionally adding a specific additive to the electrolyte.

8. A computer program stored in a computer-readable medium, comprising:
commands for predicting dendrite growth using one or more processors,
wherein the commands include:
calculating an electronegativity of electrode atoms and electrolyte atoms;
calculating partial charges of the electrode atoms and the electrolyte atoms from the electronegativity;
deriving an interaction between the electrode atoms and the electrolyte atoms on the basis of the partial charges;
determining whether a chemical reaction occurs between the electrode atoms and the electrolyte atoms on the basis of the interaction;
deriving a variation in partial charge of the electrode atoms on the basis of whether the chemical reaction occurs; and
predicting dendrite growth of the electrode atoms on the basis of the variation in partial charge.

9. The computer program of claim 8, wherein the predicting of the dendrite growth of the electrode atoms on the basis of the variation in partial charge includes predicting dendrite growth when a value of the partial charge of the electrode atoms is less than or equal to a preset value.

10. The computer program of claim 8, wherein the determining of whether the chemical reaction occurs between the electrode atoms and the electrolyte atoms on the basis of the interaction includes determining that the electrode atoms and the electrolyte atoms are bonded and have undergone a chemical reaction when a value of a distance (r) between the electrode atom and the electrolyte atom, which is derived from the interaction, is less than or equal to a preset value.

11. The computer program of claim 8, wherein the deriving of the interaction between the electrode atoms and the electrolyte atoms on the basis of the partial charges includes deriving an interaction on the basis of an interaction energy (E_{system}) between the electrode atoms and the electrolyte atoms, which is derived from the partial charges.

12. The computer program of claim 8, wherein the calculating of the partial charges of the electrode atoms and the electrolyte atoms from the electronegativity includes calculating the partial charges through a variation in electronegativity with respect to a voltage applied to the electrode atoms and the electrolyte atoms.

13. The computer program of claim 8, wherein the electrode atom is an anode electrode atom.

14. The computer program of claim 8, further comprising confirming that dendrite growth is suppressed by additionally adding a specific additive to the electrolyte.
